(19) United States
(12) Patent Application Publication
(10) Pub. No.: US 2011/0316001 A1
(43) Pub. Date: Dec. 29, 2011

(54) METHOD FOR GROWING GROUP III-V NITRIDE FILM AND STRUCTURE THEREOF

(75) Inventors: Wei I Lee, Hsinchu City (TW); Hsin Hsiung Huang, Hsinchu City (TW); Kuei Ming Chen, Taipei County (TW); Yen Hsien Yeh, Taipei County (TW)

(73) Assignee: NATIONAL CHIAO TUNG UNIVERSITY, Hsinchu (TW)

(21) Appl. No.: 13/226,951

(22) Filed: Sep. 7, 2011

Related U.S. Application Data
(62) Division of application No. 12/573,261, filed on Oct. 5, 2009.

(30) Foreign Application Priority Data
Apr. 6, 2009 (TW) 098111418

(51) Int. Cl. H01L 29/20

(52) U.S. Cl. 257/76; 257/E29.089

(57) ABSTRACT

A method for growing a Group III-V nitride film and a structure thereof are presented. The method is carried out by hydride vapor phase epitaxy (HVPE). The method includes the steps of, inter alia, slowly epitaxially growing a temperature ramping nitride layer on a substrate by rising a first growth temperature of 900-950° C. to a second growth temperature of 1000-1050° C. at a temperature-rising rate of 0.5-10° C./min. The lattice quality of the temperature ramping nitride layer is slowly transformed with the layer height, so that a stress induced by lattice mismatch between a sapphire substrate and a gallium nitride (GaN) layer is relieved.

### CROSS-REFERENCE TO RELATED APPLICATIONS

This non-provisional application claims priority under 35 U.S.C. §119(a) on Patent Application No(s). 098111418 filed in Taiwan, R.O.C. on Apr. 6, 2009, the entire contents of which are hereby incorporated by reference.

### BACKGROUND

1. Field of Invention

The present invention relates to a method for growing a nitride film and a structure thereof, and more particularly to a method for growing a Group III-V nitride film and a structure thereof.

2. Related Art

In recent years, with the rapid development of researches in the photovoltaic technology and related industries, there is a strong demand of high-efficiency photovoltaic materials. Moreover, semiconductor compound materials are becoming the mainstream of photovoltaic materials due to the advantages of high luminance performance, long life cycle, wide range of energy gap modulation, small element structure, and low price. Especially, Group III-V nitride materials are the mainstream materials for current light-emitting elements. Furthermore, current researches and industrial applications related to Group III-V nitride semiconductors mostly focus on materials such as gallium nitride (GaN), aluminum nitride (AlN), and indium nitride (InN).

However, there is a problem for nitride semiconductor materials that the lattice match between a material such as GaN grown on a substrate and the substrate is poor. Taking a commonly used sapphire substrate and GaN as an example for illustration, the difference between the lattice constants of the sapphire substrate and GaN is up to about 16%, and the difference between the thermal expansion coefficients of the two materials is up to 35%. It can be seen that for GaN grown on the sapphire substrate, a stress and defects are easily generated at an interface there-between, and a breakage may also occur in a cooling process due to the great difference between the thermal expansion coefficients.

In view of this, currently, methods such as void-assisted separation (VAS), facet controlled epitaxial lateral overgrowth (FACELO), and epitaxially lateral overgrowth (ELOG) are usually adopted to solve the lattice mismatch problem, so as to prevent the GaN substrate from breaking However, when such methods are adopted to prepare a GaN substrate, an additional process such as a lithography process needs to be performed, or additional layers of other materials need to be grown. As a result, the fabrication process becomes quite complex, and the yield rate is not high. Therefore, it is a problem to be solved by those skilled in the art to develop a method that can prevent the GaN substrate from breaking, simplify the process, and improve the yield rate.

### SUMMARY OF THE INVENTION

Accordingly, the present invention is a method for growing a Group III-V nitride film and a structure thereof, so as to prevent the GaN substrate from breaking, simplify the process, and improve the yield rate.

A method for growing a Group III-V nitride film of the present invention is carried out by hydride vapor phase epitaxy (HVPE). Firstly, a nitride buffer layer is grown on a substrate, and then a low-temperature nitride layer is grown on the substrate at a first growth temperature of 900-950° C. Next, a temperature ramping nitride layer is grown on the low-temperature nitride layer by slowly rising the first growth temperature to a second growth temperature of 1000-1050° C. at a temperature-rising rate of 0.5-10° C./min. Afterward, a high-temperature nitride layer is grown on the temperature ramping nitride layer at the second growth temperature.

Furthermore, a temperature ramping nitride layer may be directly epitaxially grown on the substrate slowly by controlling the temperature-rising rate of the temperature ramping nitride layer according to the requirement for film thickness. Therefore, the step of growing the nitride buffer layer, the low-temperature nitride layer, or the high-temperature nitride layer can be omitted.

A GaN substrate of the present invention at least comprises a substrate and a nitride film grown on the substrate. A lattice structure of the nitride film slowly transforms into a regularly arranged single-crystal structure along a growth thickness of the nitride film.

Moreover, the desired nitride film may also be formed under different growth conditions according to the different demands of epitaxial-growth techniques, for example, by controlling gas pressures or a reactive gas flow rate ratio.

Therefore, according to the method for growing a Group III-V nitride film and the structure thereof of the present invention, when a temperature ramping nitride layer is epitaxially grown on a substrate at a low temperature-rising rate, the lattice quality of the temperature ramping nitride layer of the present invention is slowly transformed the layer height. Thus, through the method of the present invention, not only a stress induced by lattice mismatch between a sapphire substrate and the nitride layer can be relieved, but also a high quality and less defective nitride substrate can be formed without performing a complex process.

### BRIEF DESCRIPTION OF THE DRAWINGS

The present invention will become more fully understood from the detailed description given herein below for illustration only, and thus are not limitative of the present invention, and wherein:

FIGS. 1A-1D are schematic cross-sectional views illustrating steps for fabricating a GaN thick film substrate according to a first embodiment of the present invention;

FIG. 2 is a schematic view of curves obtained by analyzing and measuring a Raman scattering spectrum of a GaN thick film substrate prepared by a manufacturing method according to an embodiment of the present invention;

FIG. 3 shows an oscillation curve obtained by measuring a freestanding GaN thick film stripped from a GaN thick film substrate according to an embodiment of the present invention by high resolution X-ray diffraction (HRXRD);

FIG. 4 shows an image of a GaN thick film substrate according to an embodiment of the present invention observed by a cathodoluminescence (CL);

FIG. 5 is a schematic cross-sectional view of a GaN thick film substrate prepared according to another embodiment of the present invention;

FIG. 6 is a schematic cross-sectional view of a GaN thick film substrate prepared according to still another embodiment of the present invention;

FIGS. 7-8 are schematic cross-sectional views of a GaN thick film substrate prepared according to still another embodiment of the present invention; and

FIGS. 9-10 are schematic cross-sectional views of a GaN thick film substrate prepared according to still another embodiment of the present invention.

### DETAILED DESCRIPTION OF THE INVENTION

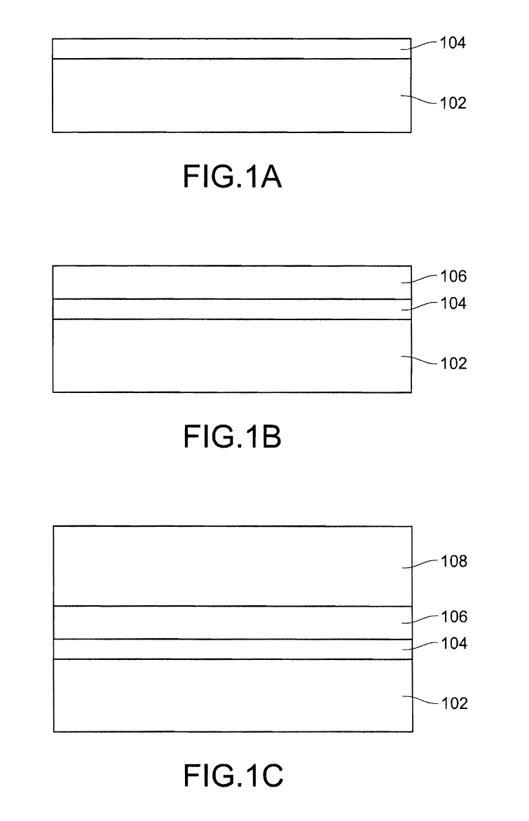

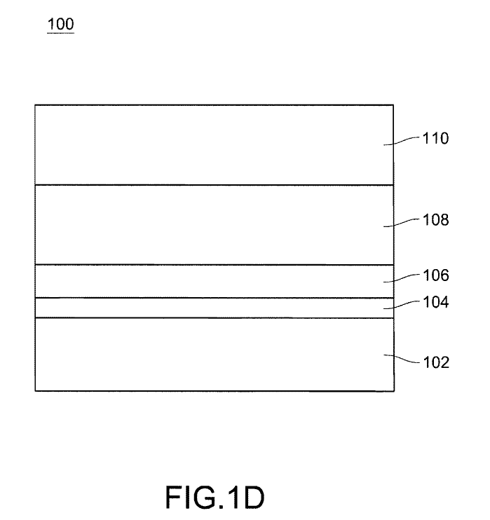

In the method for growing a Group III-V nitride film and the structure thereof of the present invention, a Group III-V nitride film is grown on a substrate by hydride vapor phase epitaxy (HVPE). The substrate may be, for example, but not limited to, a sapphire substrate, a silicon carbide (SiC) substrate, a gallium arsenide (GaAs) substrate, or a silicon substrate. The Group III-V nitride film may be made of, for example, but not limited to, gallium nitride (GaN), aluminum nitride (AlN), and indium nitride (InN), aluminum gallium nitride (AlGaN), or other semiconductor materials. The following embodiments are described by taking a sapphire substrate and GaN as an example. However, the present invention is not limited to this embodiment, and various variations may be made by those of ordinary skill in the art without departing from the spirit of the present invention. FIGS. 1A-1D are schematic cross-sectional views illustrating steps for fabricating a GaN thick film substrate according to a first embodiment of the present invention. As shown in FIG. 1A, a GaN buffer layer 104 is grown on a sapphire substrate 102. The GaN buffer layer 104 may be formed by, for example, metal organic chemical vapor phase deposition (MOCVD) or pulse laser deposition (PLD). A thickness of the GaN buffer layer 104 may be flexibly adjusted as demands, for example, the thickness may be 1-3 μm.

Then, as shown in FIG. 1B, a low-temperature GaN layer 106 is grown on the GaN buffer layer 104 at a first growth temperature of 900-950° C. A thickness of the low-temperature GaN layer 106 is 10-50 μm. In this embodiment, the low-temperature GaN layer 106 is grown at a first growth temperature of 950° C.

Afterward, as shown in FIG. 1C, a temperature ramping GaN layer 108 is slowly grown on the low-temperature GaN layer 106. The temperature of the temperature ramping GaN layer 108 slowly rises from the first growth temperature to a second growth temperature of 1000-1050° C. at a temperature-rising rate of 0.5-10° C./min. In such a manner, a lattice structure of the temperature ramping GaN layer 108 slowly transforms into a regularly arranged single-crystal structure along a growth thickness of the temperature ramping GaN layer 108. That is to say, for the lattice structure of the temperature ramping GaN layer 108, the lattice arrangement is proportional to the growth thickness thereof. Therefore, the greater the growth thickness of the temperature ramping GaN layer 108 is, the more regularly the lattices are arranged. In addition, the growth thickness of the temperature ramping GaN layer 108 is 10-200 μm. Furthermore, the temperature-rising rate for epitaxially growing the temperature ramping GaN layer 108 may be varied according to different platforms. In this embodiment, the temperature ramping GaN layer 108 is epitaxially grown by slowly rising a first growth temperature of 950° C. to a second growth temperature of 1050° C. at a temperature-rising rate of 1° C./min.

As shown in FIG. 1D, a high-temperature GaN layer 110 is then grown on the temperature ramping GaN layer 108 at the second growth temperature. A thickness of the high-temperature GaN layer is 10-150 μm. In such a manner, a GaN thick film substrate 100 is completed. In this embodiment, the high-temperature GaN layer 110 is grown at the second growth temperature of 1050° C.

It should be particularly noted that, as the temperature ramping GaN layer 108 is epitaxially grown on the low-temperature GaN layer 106 at a low temperature-rising rate, the lattice quality of the temperature ramping GaN layer 108 of the present invention slowly transforms with the layer height. Thus, the temperature ramping GaN layer 108 can relieve a stress induced by lattice mismatch between the sapphire substrate and the GaN layer, thus forming a high quality and less defective GaN thickfilm substrate.

The GaN thickfilm substrate prepared in this embodiment will be analyzed and measured by different technologies, respectively.

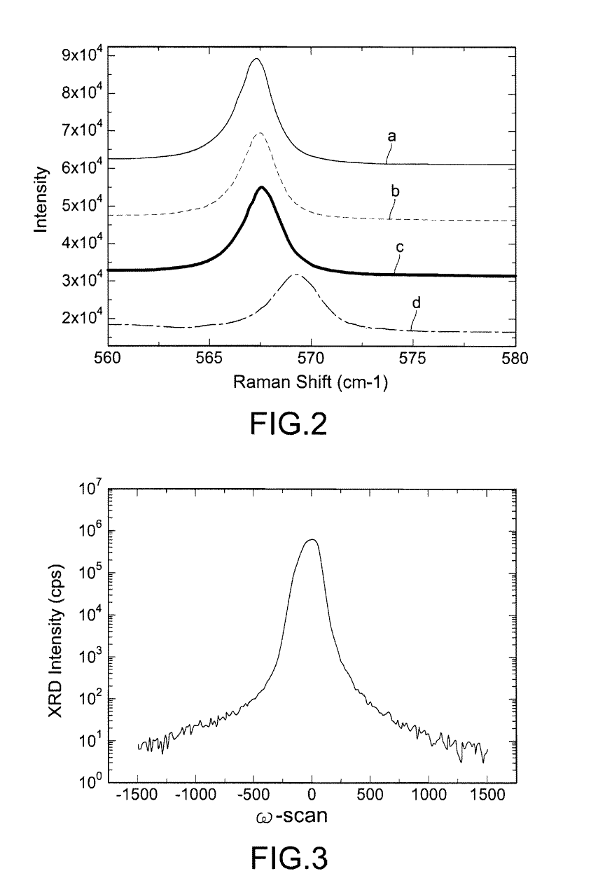

FIG. 2 is a schematic view of curves obtained by analyzing and measuring a Raman scattering spectrum of a GaN thickfilm substrate prepared by a manufacturing method according to an embodiment of the present invention. As shown in FIG. 2, Curves a-c respectively represent the high-temperature GaN layer 110, the temperature ramping GaN layer 108, and the low-temperature GaN layer 106 in the first embodiment of the present invention; and Curve d represents a conventional GaN thickfilm substrate as a control group. The conventional GaN thickfilm substrate refers to a structure obtained by directly growing a high-temperature GaN layer on a sapphire substrate. Moreover, Raman shifts of peaks of Curves a-d are respectively 567.3, 567.5, 567.5, and 569.4 cm-1, and compressive stresses corresponding to these values are respectively 0.07, 0.12, 0.12, and 0.5 GPa. It can be seen from the measured values that as compared with the conventional GaN thickfilm substrate, the stress of the GaN thickfilm substrate obtained by the method of the present invention can be relieved by the temperature ramping GaN layer, and the GaN thickfilm substrate can be thus prevented from breaking

FIG. 3 shows an oscillation curve obtained by measuring a freestanding GaN thick film stripped from a GaN thickfilm substrate according to an embodiment of the present invention by high resolution X-ray diffraction (HRXRD). As shown in FIG. 3, a full width at half maximum (FWHM) of the waveform of the freestanding GaN thick film is 156.7 arcsec.

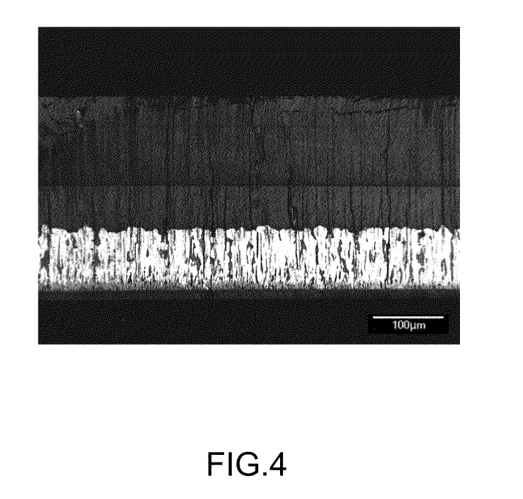

FIG. 4 shows an image of a GaN thickfilm substrate according to an embodiment of the present invention observed by a cathodoluminescence (CL). As shown in FIG. 4, in the lattice structure of the temperature ramping GaN layer 108, the lattices are quite regularly arranged; and the greater the growth thickness of the temperature ramping GaN layer 108 is, the more regularly the lattices are arranged.

It can be seen from the measured and analyzed values that, through the method of the present invention, not only the stress induced by lattice mismatch between the sapphire substrate and the GaN layer can be relieved, but also a high quality and less defective GaN thickfilm substrate can be formed without performing a complex process.

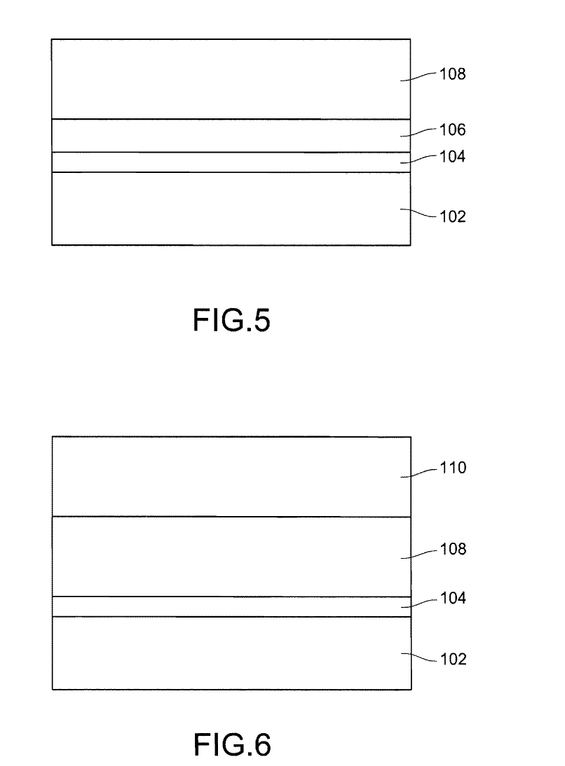

In another embodiment of the present invention, the step of growing the high-temperature GaN layer may also be omitted by controlling the temperature-rising rate of the temperature ramping GaN layer. FIG. 5 is a schematic cross-sectional view of a GaN thickfilm substrate prepared according to another embodiment of the present invention. Different from the first embodiment, the step of growing the high-temperature GaN layer is omitted in this embodiment. In particular, when the desired film thickness is not high, the temperature-rising rate may be controlled during performing the step of growing the temperature ramping GaN layer 108 until a growth temperature slowly rises to a second growth temperature. In such a manner, a high quality GaN thickfilm substrate can be obtained without additionally forming a high-temperature GaN layer, as shown in FIG. 5. The growth temperatures and other conditions used in this embodiment are the same as those used in the first embodiment, so the details will not be described herein again.

In still another embodiment of the present invention, the step of growing the low-temperature GaN layer may also be omitted by controlling the temperature-rising rate of the temperature ramping GaN layer. FIG. 6 is a schematic cross-sectional view of a GaN thickfilm substrate prepared according to still another embodiment of the present invention. Different from the first embodiment, the step of growing the low-temperature GaN layer is omitted in this embodiment. In particular, as shown in FIG. 6, after a GaN buffer layer 104 is grown on a sapphire substrate 102, a temperature ramping GaN layer 108 is directly epitaxially grown by slowly rising a first growth temperature to a second growth temperature at a temperature-rising rate of 0.5-10° C./min. Afterward, a high-temperature GaN layer 110 is grown on the temperature ramping GaN layer 108 at the fixed second growth temperature. The growth temperatures used in this embodiment are the same as those used in the first embodiment, so the details will not be described herein again.

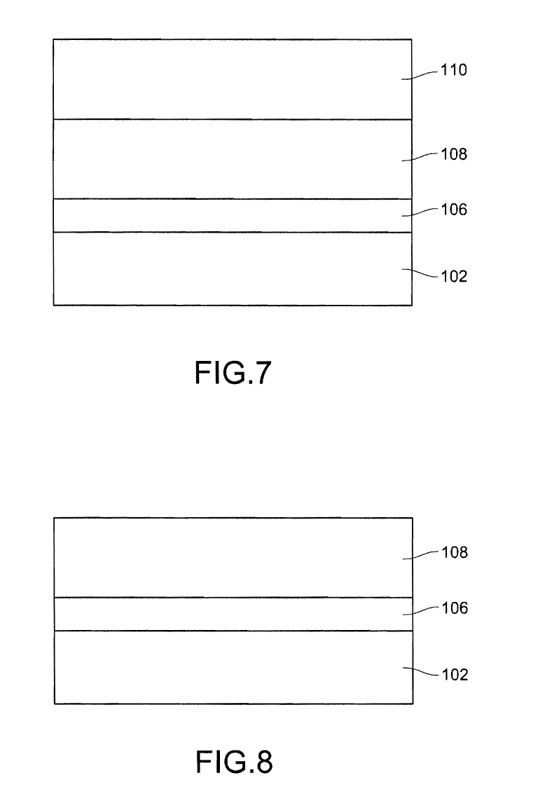

In still another embodiment of the present invention, the GaN buffer layer may be not necessary to be formed; instead, a low-temperature GaN layer, a temperature ramping GaN layer, and/or a high-temperature GaN layer are directly grown on a sapphire substrate in sequence. FIG. 7 is a schematic cross-sectional view of a GaN thickfilm substrate prepared according to still another embodiment of the present invention. Different from the first embodiment, the step of growing the GaN buffer layer is omitted in this embodiment. In particular, as shown in FIG. 7, a low-temperature GaN layer 106 is directly grown on a sapphire substrate 102 at a first growth temperature. Then, a temperature ramping GaN layer 108 is epitaxially grown by slowly rising the first growth temperature to a second growth temperature at a temperature-rising rate of 0.5-10° C./min. Afterward, a high-temperature GaN layer 110 is grown on the temperature ramping GaN layer 108 at the second growth temperature. The growth temperatures and other conditions used in this embodiment are the same as those used in the first embodiment, so the details will not be described herein again. Moreover, the step of growing the high-temperature GaN layer can also be omitted by controlling the temperature-rising rate of the temperature ramping GaN layer 108 according to the desired film thickness, so as to form a GaN thickfilm substrate structure as shown in FIG. 8.

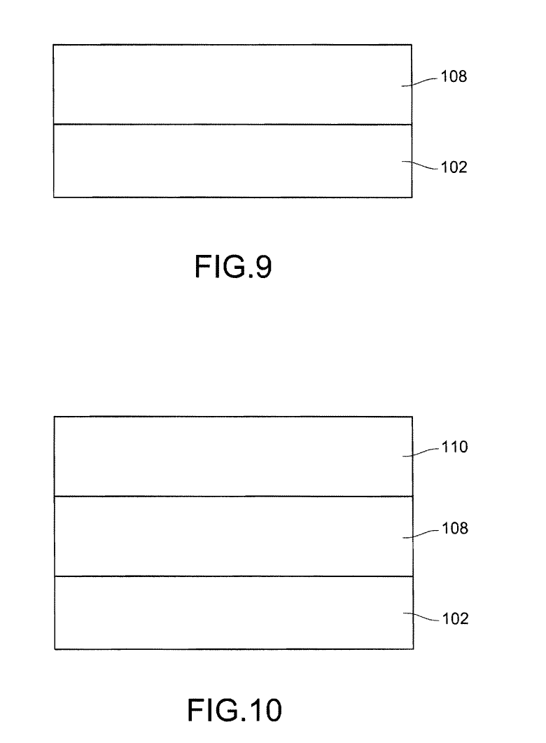

In still another embodiment of the present invention, a temperature ramping GaN layer 108 may be directly grown on a sapphire substrate as required. FIG. 9 is a schematic cross-sectional view of a GaN thickfilm substrate prepared according to still another embodiment of the present invention. As shown in FIG. 9, a temperature ramping GaN layer 108 is directly grown on a sapphire substrate 102 by slowly rising a first growth temperature to a second growth temperature at a temperature-rising rate of 0.5-10° C./min. The first growth temperature is 900-950° C., and the second growth temperature is 1000-1050° C. In practice, when the desired film thickness is not high, the required film thickness can be achieved by controlling the temperature-rising rate. Alternatively, as shown in FIG. 10, a high-temperature GaN layer 110 may also be grown on the temperature ramping GaN layer 108 at the second growth temperature.

In addition to the above method of growing the nitride film (i.e., the temperature ramping nitride layer) by controlling the temperature-rising rate, the desired nitride film may also be formed by controlling gas pressures or gas flow rates. In particular, the method of controlling the gas pressures is illustrated as an example. A nitride film is slowly grown on a substrate by slowly reducing a first gas pressure of 600-760 torr to a second gas pressure of 250-300 torr at a rate of 1-10 torr/min, such that a lattice structure of the nitride film slowly transforms into a regularly arranged single-crystal structure along a growth thickness of the nitride film. The growth temperatures and other conditions used in this embodiment are the same as those used in the foregoing embodiments, so the details will not be described herein again.

Alternatively, the desired nitride film may be formed by controlling a reactive gas flow rate ratio of the Group III and Group V nitride. In particular, a nitride film is slowly grown on a substrate by slowly increasing a first reactive gas flow rate ratio of 20-40 to a second reactive gas flow rate ratio of 80-100 at a flow rate of 0.5-1/min, such that a lattice structure of the nitride film slowly transforms into a regularly arranged single-crystal structure along a growth thickness of the nitride film. The first reactive gas flow rate ratio and the second reactive gas flow rate ratio refer to two different ratios of reactive gases. For example, if the reactive gases are NH₃ and HCl, and are respectively introduced at flow rates of 2.0 L/min and 0.05 L/min, the reactive gas flow rate ratio is 40. The growth temperatures and other conditions used in this embodiment are the same as those used in the foregoing embodiments, so the details will not be described herein again.

1-18. (canceled)

19. A gallium nitride (GaN) thick film substrate, comprising:
a substrate; and
a nitride film, grown on the substrate, wherein the nitride film has a lattice structure that slowly transforms into a regularly arranged single-crystal structure along a growth thickness of the nitride film.

20. The GaN thick film substrate according to claim 19, wherein the growth thickness of the nitride film is 10-200 μm.

21. The GaN thick film substrate according to claim 19, further comprising a first nitride layer grown between the substrate and the nitride film.

22. The GaN thickfilm substrate according to claim 21, wherein a thickness of the first nitride layer is 10-50 μm.

23. The GaN thickfilm substrate according to claim 21, further comprising a second nitride layer grown on the nitride film.

24. The GaN thickfilm substrate according to claim 23, wherein the second nitride layer has a thickness of 10-150 μm.

25. The GaN thickfilm substrate according to claim 21, further comprising a nitride buffer layer grown between the substrate and the first nitride layer.
